(19) United States
(12) Patent Application Publication
(10) Pub. No.: US 2014/0265624 A1
(43) Pub. Date: Sep. 18, 2014

(54) PIEZOELECTRIC TRANSFORMER, PIEZOELECTRIC TRANSFORMER MODULE, AND WIRELESS POWER TRANSMISSION SYSTEM

(71) Applicant: MURATA MANUFACTURING CO., LTD., Nagaokakyo-Shi (JP)

(72) Inventors: Keiichi Ichikawa, Nagaokakyo-Shi (JP); Takaaki Asada, Nagaokakyo-Shi (JP); Takashi Kawada, Nagaokakyo-Shi (JP)

(73) Assignee: MURATA MANUFACTURING CO., LTD., Nagaokakyo-Shi (JP)

(21) Appl. No.: 14/291,703

(22) Filed: May 30, 2014

Related U.S. Application Data
(63) Continuation of application No. PCT/JP2012/080268, filed on Nov. 22, 2012.

(30) Foreign Application Priority Data
Dec. 1, 2011 (JP) 2011-263553

(51) Int. Cl. H01L 41/107; H02J 17/00

(52) U.S. Cl. CPC H01L 41/107; H02J 17/00
USPC 307/104; 310/366; 310/348; 310/318; 310/359

(57) ABSTRACT

A piezoelectric transformer includes a rectangular plate-shaped piezoelectric board having a length L in a longitudinal direction. In the piezoelectric board, five regions having a length L/5 are formed. In the two of regions, inner electrodes are formed in a thickness direction and conducted to outer electrodes provided in these regions. In a third region, outer electrodes are provided. The two regions of the piezoelectric board are polarized in the thickness direction, and two adjacent regions thereof are polarized in the longitudinal direction, and the third region is non-polarized. When a voltage is applied to the outer electrodes, the piezoelectric board expands and contracts in the longitudinal direction due to a piezoelectric effect. Thus, a piezoelectric transformer which enables high-efficient energy conversion even when a driving frequency is increased and a wireless power transmission system using the piezoelectric transformer are provided.

### CROSS REFERENCE TO RELATED APPLICATIONS

The present application is a continuation of PCT/JP2012/080268 filed Nov. 22, 2012, which claims priority to Japanese Patent Application No. 2011-263553, filed Dec. 1, 2011, the entire contents of each of which are incorporated herein by reference.

### FIELD OF THE INVENTION

The present invention relates to a piezoelectric transformer, a piezoelectric transformer module, and a wireless power transmission system which are allowed to be used when a driving frequency is increased.

### BACKGROUND OF THE INVENTION

In recent years, in order to eliminate the inconvenience of connecting a charging cable to an electronic apparatus such a cellular phone or a mobile PC when the electronic apparatus is charged, wireless power transmission has been proposed in which an electronic apparatus is allowed to be charged only by placing the electronic apparatus on a charging apparatus. As wireless power transmission, an electric field coupling method has been known in which power is transmitted from a power transmitting apparatus (charging apparatus) side to a power receiving apparatus (electronic apparatus) side by using a quasi-static electric field (e.g., see Patent Document 1).

The power transmission system described in Patent Document 1 includes a power transmitting apparatus and a power receiving apparatus each including a passive electrode and an active electrode. When the active electrode of the power transmitting apparatus and the active electrode of the power receiving apparatus come close to each other via a gap, a strong electric field is formed between these two electrodes, and these electrodes are coupled to each other through the electric field. This electric field coupling enables wireless power transmission between the apparatuses.

Meanwhile, in general, in a method for increasing the transmission efficiency of a power transmission system, it is effective to incorporate a low-loss resonant circuit. The resonant circuit includes an inductor and an electrostatic capacity of a coupling portion of the power transmitting apparatus and the power receiving apparatus. In order to incorporate a resonant circuit into an apparatus that has been made smaller and thinner in recent years, it is a challenge to achieve a reduction in the size of the resonant circuit and a reduction in the loss of the resonant circuit. As a method for solving the challenge, it is considered effective to use a piezoelectric device as the inductor.

FIG. 22 is a diagram showing a piezoelectric device described in Patent Document 2 and displacement of the piezoelectric device. Patent Document 2 discloses a Rosen tertiary, third order type piezoelectric transformer having a symmetric structure which is one of piezoelectric devices as shown in FIG. 22. The piezoelectric transformer described in Patent Document 2 includes a rectangular plate-shaped piezoelectric board 200. Both end portions of the piezoelectric board 200 are provided with planar input electrodes 201A and 201B and input electrodes 202A and 202B on upper and lower surfaces to form a drive portion, and are polarized in the thickness direction. In addition, a center portion of the piezoelectric board 200 is provided with output electrodes 203A and 203B on the upper and lower surfaces to form a power generation portion, and is polarized in the length direction.

With regard to vibration of the piezoelectric transformer, as shown in a graph in the lower part of FIG. 22, so-called node points where the vibration displacement becomes zero are provided at the center in the longitudinal direction and at positions away from the center in the directions toward both ends by λ/2, and the displacement becomes maximum at both ends and at points inward from both ends by λ/2. When a voltage is applied between the input electrodes 201A and 201B and between the input electrodes 202A and 202B, a stepped-up high voltage is extracted from the output electrode 203A due to the action of a piezoelectric effect and an inverse piezoelectric effect.

Patent Document 1: Japanese Unexamined Patent Application Publication (Translation of PCT Application) No. 2009-531009

Patent Document 2: Japanese Patent No. 3080052

In the wireless power transmission using an electric field coupling method, a capacitive coupling impedance between the active electrodes is desired to be reduced in order to reduce the size of the power receiving apparatus. In this case, it is possible to realize this by increasing the frequency of a voltage outputted from the power transmitting apparatus. However, when the device size of the piezoelectric transformer is reduced in response to a demand for size reduction of the power receiving apparatus, the following problems arise: the vibration state of the piezoelectric transformer is easily affected by a mounted portion, the withstand voltage is decreased, the temperature easily rises due to a small thermal capacity, heat is generated by the piezoelectric transformer, and the conversion efficiency is also decreased.

### SUMMARY OF THE INVENTION

Therefore, it is an object of the present invention to provide a piezoelectric transformer, a piezoelectric transformer module, and a wireless power transmission system which enable high-efficient energy conversion even when a driving frequency is increased.

A piezoelectric transformer according to the present invention is a piezoelectric transformer using a fifth-order longitudinal vibration mode. The piezoelectric transformer includes a piezoelectric board having a length of 5λ/2, a width smaller than λ/2, and a thickness smaller than λ/2. The piezoelectric board has first to fifth regions obtained by dividing the piezoelectric board into five equal portions along a length direction. The first region and the fifth region are polarized with a thickness direction or the length direction as a polarization direction. The second region and the fourth region are polarized with the length direction as a polarization direction. The third region is non-polarized. The piezoelectric transformer further includes: a first electrode and a second electrode provided in each of the first region and the fifth region and arranged along the polarization direction so as to be opposed to each other; and a third electrode provided at a position including boundaries between: the third region; and the second region and the fourth region.

In the configuration, the third region at the center portion of the five equal regions into which the piezoelectric board is divided along the length direction is non-polarized, and the other regions are polarized. The opposed first electrode and second electrode are provided in the polarized region. When a voltage is applied to the electrodes, each region in which the electrodes are provided has a longitudinal effect and/or a transverse effect. For example, when a voltage is applied to the electrodes provided in the regions at both end portions in the length direction of the piezoelectric board, a higher-order longitudinal vibration mode in the length direction of the piezoelectric board is excited, and it is possible to extract a stepped-up voltage from the third electrode in the third region at the center due to a piezoelectric effect and an inverse piezoelectric effect.

The piezoelectric body included in the piezoelectric transformer has a length L, and each region has a length L/5. Thus, when a driving frequency is used as a frequency at which resonance is performed in a higher-order mode (5λ/2), a standing wave of λ/2 is generated at both end portions of, at the center portion of, and between both end portions and the center portion of, the piezoelectric body. As a result, the size of the piezoelectric transformer is 5/2λ of a wave length λ and is larger than that in the case of using a 3λ/2 longitudinal vibration mode, and thus it is possible to prevent heat generation caused by vibration, namely, a decrease in conversion efficiency.

In addition, in the piezoelectric transformer, its vibration displacement becomes small at the center in the length direction of each of electrodes provided at both end portions and the center portion of the piezoelectric body, and the piezoelectric transformer is supported and wired at those portions. Thus, vibration of the piezoelectric transformer is not inhibited, and it is possible to prevent a decrease in connection reliability caused by the displacement of the piezoelectric body after mounting. Furthermore, since the center portion which becomes a stress-concentrated point is non-polarized, it is possible to prevent stress from being concentrated on a polarization interface to break the piezoelectric body. Moreover, since it is possible to lengthen the distances between both end portions and the center portion of the piezoelectric body as compared to the related art (Cited Document 2), it is possible to improve a withstand voltage at these portions.

A length of the piezoelectric board in one of a width direction and the thickness direction may be λ/4, and a length thereof in the other of the width direction and the thickness direction may not be longer than λ/4.

In the configuration, it is possible to avoid unnecessary vibration in the width direction and the thickness direction from being coupled to vibration in the longitudinal direction to decrease power transmission efficiency.

The first electrode and the second electrode may be provided so as to be opposed to each other in the thickness direction when polarization directions in the first region and the fifth region are the thickness direction; and may be provided so as to be opposed to each other in the length direction when the polarization directions in the first region and the fifth region are the length direction.

In the configuration, due to a transverse effect or a longitudinal effect of the first region and the fifth region, the piezoelectric board vibrates in the fifth-order longitudinal vibration mode in the length direction. As a result, due to a piezoelectric longitudinal effect of the second region and the fourth region, it is possible to extract an output voltage from the third region at the center.

The piezoelectric board may be supported at the third region, the first region, and the fifth region.

In the configuration, since the piezoelectric transformer is supported at node point portions of vibration at which displacement becomes small, it is possible to prevent vibration of the piezoelectric transformer from being inhibited.

A piezoelectric transformer according to the present invention is a piezoelectric transformer using a fifth-order longitudinal vibration mode. The piezoelectric transformer includes a piezoelectric board having a length of 5λ/2, a width smaller than λ/2, and a thickness smaller than λ/2. The piezoelectric board has first to fifth regions obtained by dividing the piezoelectric board into five equal portions along a length direction. The first region and the fifth region are polarized with a thickness direction or the length direction as a polarization direction. The second region and the fourth region are polarized with the thickness direction as a polarization direction. The third region is non-polarized. The piezoelectric transformer further includes: a first electrode and a second electrode provided in each of the first region and the fifth region and arranged along the polarization direction so as to be opposed to each other; and a third electrode and a fourth electrode provided in each of the second region and the fourth region and arranged along the polarization direction so as to be opposed to each other.

In the configuration, due to a transverse effect or a longitudinal effect of the first region and the fifth region, the piezoelectric board vibrates in the fifth-order longitudinal vibration mode in the length direction. As a result, due to a piezoelectric transverse effect of the second region and the fourth region, it is possible to extract an output voltage from the second region and the fourth region.

The piezoelectric board may be supported at the first region, the second region, the fourth region, and the fifth region.

In the configuration, since the piezoelectric transformer is supported at node point portions of vibration at which displacement becomes small, it is possible to prevent vibration of the piezoelectric transformer from being inhibited.

A piezoelectric transformer according to the present invention is a piezoelectric transformer using a (2n+1)-order longitudinal vibration mode (n is an integer that is not smaller than 3). The piezoelectric transformer includes a piezoelectric board having a length of (2n+1)×λ/2, a width smaller than λ/2, and a thickness smaller than λ/2. The piezoelectric board has first to (2n+1)th regions obtained by dividing the piezoelectric board into (2n+1) equal portions along a length direction. The first region to the (n−k)th region (k is a positive integer smaller than n) and the (n+k+2)th region to the (2n+1)th region are polarized with a thickness direction as a polarization direction. The (n−k+1)th region to nth region and the (n+2)th region to the (n+k+1)th region are polarized with the length direction as a polarization direction. The (n+1)th region is non-polarized. The piezoelectric transformer further includes: a first electrode and a second electrode provided in each of the first region to the (n−k)th region and the (n+k+2)th region to the (2n+1)th region and arranged along the polarization direction so as to be opposed to each other; and a third electrode provided at a position including boundaries between the (n−k+1)th region to the nth region and the (n+2)th region to the (n+k+1)th region.

In the configuration, it is possible to use even a higher-order mode such as a seventh order, a ninth order, or an eleventh order.

The piezoelectric transformer according to the present invention may be configured such that n=2m (m is a positive integer) and k=m.

In the configuration, in the case of a higher-order mode such as a seventh order, an eleventh order, or a fifteenth order, the number of the regions polarized in the thickness direction and the number of the regions polarized in the length direction are equal to each other, and it is possible to make a step-up ratio (or step-down ratio) the highest.

According to the present invention, when the driving frequency is used as a frequency at which resonance is performed in a higher-order mode (5λ/2), a standing wave of λ/2 is generated at both end portions of, at the center portion of, and between both end portions and the center portion of, the piezoelectric body. As a result, the size of the piezoelectric transformer is not excessively small relative to the wave length λ, it is possible to prevent heat generation caused by vibration, namely, a decrease in conversion efficiency, and thus it is possible to increase power. In addition, since the piezoelectric transformer is supported and wired at a displacement minimum portion at the center in the length direction of each of the electrodes at both end portions and the center portion of the piezoelectric body, vibration of the piezoelectric transformer is not inhibited, and it is possible to prevent a decrease in connection reliability caused by the displacement of the piezoelectric body after mounting. Furthermore, it is possible to prevent stress from being concentrated on a polarization interface to break the piezoelectric body. Moreover, since it is possible to lengthen the distances between both end portions and the center portion of the piezoelectric body as compared to the related art (Cited Document 2), it is possible to improve a withstand voltage at these portions.

### BRIEF DESCRIPTION OF DRAWINGS

FIG. 1 is a perspective view of a piezoelectric transformer according to Embodiment 1.

FIG. 2A is a cross-sectional view taken along a II-II line in FIG. 1.

FIG. 2B is a diagram showing a modification of FIG. 2A.

FIG. 3A is a cross-sectional view taken along a IIIA-IIIA line in FIG. 1.

FIG. 3B is a cross-sectional view taken along a IIIB-IIIB line in FIG. 1.

FIG. 4 is a diagram showing wiring of the piezoelectric transformer used in a step-up circuit and a simplified structure of the piezoelectric transformer 1.

FIG. 5 is a diagram showing wiring of the piezoelectric transformer used in a step-down circuit and a simplified structure of the piezoelectric transformer.

FIG. 6 is a graph showing output power when a width W is varied.

FIG. 7 is an external perspective view of one piezoelectric transformer composed of a plurality of piezoelectric transformers according to Embodiment 1.

FIG. 8 is an external perspective view of one piezoelectric transformer composed of a plurality of piezoelectric transformers according to Embodiment 1.

FIG. 9 is a side cross-sectional view of a piezoelectric transformer according to Embodiment 2.

FIG. 10 is a diagram showing a circuit configuration of a wireless power transmission system.

FIG. 11 is a diagram showing a circuit configuration of a wireless power transmission system when two piezoelectric transformers are used.

FIG. 12A is a diagram illustrating a variation of a polarization direction in the piezoelectric transformer.

FIG. 12B is a diagram illustrating a variation of the polarization direction in the piezoelectric transformer.

FIG. 12C is a diagram illustrating a variation of the polarization direction in the piezoelectric transformer.

FIG. 13A is a diagram illustrating a variation of the polarization direction in the piezoelectric transformer.

FIG. 13B is a diagram illustrating a variation of the polarization direction in the piezoelectric transformer.

FIG. 14A is a diagram illustrating a variation of the polarization direction in the piezoelectric transformer.

FIG. 14B is a diagram illustrating a variation of the polarization direction in the piezoelectric transformer.

FIG. 15A is a diagram showing a piezoelectric transformer when regions of input and output portions are changed.

FIG. 15B is a diagram showing a piezoelectric transformer when the regions of the input and output portions are changed.

FIG. 15C is a diagram showing a piezoelectric transformer when the regions of the input and output portions are changed.

FIG. 15D is a diagram showing a piezoelectric transformer when the regions of the input and output portions are changed.

FIG. 16A is a diagram showing a piezoelectric transformer when the regions of the input and output portions are changed.

FIG. 16B is a diagram showing a piezoelectric transformer when the regions of the input and output portions are changed.

FIG. 16C is a diagram showing a piezoelectric transformer when the regions of the input and output portions are changed.

FIG. 16D is a diagram showing a piezoelectric transformer when the regions of the input and output portions are changed.

FIG. 17A is a cross-sectional view of a piezoelectric transformer which vibrates in a (7λ/2) resonant mode.

FIG. 17B is a cross-sectional view of the piezoelectric transformer which vibrates in the (7λ/2) resonant mode.

FIG. 18A is a cross-sectional view of a piezoelectric transformer which vibrates in a (9λ/2) resonant mode.

FIG. 18B is a cross-sectional view of the piezoelectric transformer which vibrates in the (9λ/2) resonant mode.

FIG. 19 is a cross-sectional view of a piezoelectric transformer which vibrates in a (11λ/2) resonant mode.

FIG. 20 is a cross-sectional view of a piezoelectric transformer which vibrates in a {(2n+1)λ/2} resonant mode.

FIG. 21 is a graph showing a relationship between n and a step-up ratio S (or a step-down ratio) in the {(2n+1)λ/2} resonant mode.

FIG. 22 is a diagram showing a piezoelectric device described in Patent Document 2 and displacement of the piezoelectric device.

### DETAILED DESCRIPTION OF THE PREFERRED EMBODIMENTS

### Embodiment 1

FIG. 1 is a perspective view of a piezoelectric transformer according to Embodiment 1. FIG. 2A is a cross-sectional view taken along a II-II line in FIG. 1, and FIG. 2B is a diagram showing a modification of FIG. 2A. FIG. 3A is a cross-sectional view taken along a IIIA-IIIA line in FIG. 1, and FIG. 3B is a cross-sectional view taken along a IIIB-IIIB line in FIG. 1. It should be noted that FIG. 1 is a perspective view, but inner electrodes shown in FIGS. 2A, 2B, 3A, and 3B are omitted therein.

As shown in FIG. 1, the piezoelectric transformer 1 according to the present embodiment includes a rectangular plate-shaped piezoelectric board 2 having a length L, a thickness T, and a width W. The piezoelectric board 2 is formed from PZT type ceramics or the like. An outer electrode (first electrode 3A) and an outer electrode (second electrode) 3B which are opposed to each other, and an outer electrode (first electrode) 4A and an outer electrode (second electrode) 4B which are opposed to each other are formed on both end portions of the piezoelectric board 2. Outer electrodes (third electrodes) 5A and 5B which are opposed to each other are formed on a center portion of the piezoelectric board 2. As described later, the piezoelectric board 2 is polarized, and when an AC voltage is applied either between the outer electrodes 3A and 3B and the outer electrodes 4A and 4B or between the short-circuited outer electrodes 5A and 5B and the outer electrodes 4A and 4B, longitudinal vibration in the length direction is excited due to an inverse piezoelectric effect, and the entire piezoelectric board 2 vibrates. It is possible to extract a stepped-up or stepped-down voltage from between the short-circuited outer electrodes 5A and 5B and the outer electrodes 4A and 4B or from between the outer electrodes 3A and 3B and the outer electrodes 4A and 4B. It should be noted that only one of the outer electrodes 5A and 5B may be provided.

The piezoelectric transformer 1 according to the present embodiment vibrates in a (5λ/2) resonant mode. It should be noted that λ is the wave length of a higher-order mode (the (5λ/2) mode) of the vibration in the length direction. Therefore, the length L is set at (5λ/2). Here, the thickness T and the width W are preferably less than (λ/2). This is because vibrations in the thickness T and width W directions are not coupled to the vibration in the length direction, and the vibration of the entire piezoelectric transformer 1 is not unstable. In the present embodiment, as specific numeric values, L=15 mm, W=2.0 mm, and T=1.0 mm. In addition, the piezoelectric board 2 of the piezoelectric transformer 1 is divided into five equal regions in the longitudinal direction, and regions each having a length of L/5 (i.e., λ/2) in the longitudinal direction are designated by L1, L2, L3, L4, and L5.

The regions L1, L3, and L5 are input and output portions of the piezoelectric transformer 1 in which the outer electrodes are provided. When the piezoelectric transformer 1 is used as a step-up transformer, the regions L1 and L5 are input portions, and the region L3 is an output portion. In addition, when the piezoelectric transformer 1 is used as a step-down transformer, the regions L1 and L5 are output portions, and the region L3 is an input portion. In the present embodiment, the case will be described in which the piezoelectric transformer 1 is used as a step-up transformer, and a description will be given on the assumption that the regions L1 and L5 are input portions and the region L3 is an output portion.

The piezoelectric board 2 is subjected to poling treatment such that the piezoelectric board 2 is polarized in the thickness direction in the regions L1 and L5, is polarized in the longitudinal direction in the regions L2 and L4, and is non-polarized in the region L3. Examples of a method of the poling treatment include a method in which a voltage of 2 kV/mm is applied to the piezoelectric board 2 in an insulating oil at 170° C., etc.

Although described later, the centers of the regions L1, L3, and L5 in the longitudinal direction are positions (nodes) at which the displacement of the piezoelectric board 2 becomes minimum, and the piezoelectric transformer 1 is supported at the regions L1, L3, and L5 by a mounting substrate. In other words, the regions L1, L3, and L5 are connection nodes. Since the piezoelectric transformer 1 is supported at the positions at which the displacement becomes minimum, the vibration of the piezoelectric transformer 1 is not inhibited. In addition, in the regions L1, L3, and L5, the outer electrodes are formed and signal lines are wired so as to be electrically connected to the mounting substrate. Since the signal lines are wired at the positions at which the displacement becomes minimum, breakage of the signal lines due to the vibration of the piezoelectric transformer 1 is prevented and thus it is possible to enhance the mountability.

As shown in FIG. 2A, in the piezoelectric board 2, pluralities of inner electrodes 31, 41, and 51 stacked in the thickness direction of the piezoelectric board 2 are provided in the regions L1, L3, and L5, respectively. A pair of the opposed outer electrodes 3A and 3B are provided on two side surfaces of the piezoelectric board 2 in the region L1. The plurality of inner electrodes 31 are conducted to the outer electrodes 3A and 3B as shown in FIG. 3A. Specifically, the inner electrodes 31 are alternately conducted to the outer electrodes 3A and 3B such that the uppermost inner electrode 31 in the stacking direction (the thickness direction of the piezoelectric board 2) is conducted to the outer electrode 3A and the next inner electrode 31 is conducted to the outer electrode 3B. With this structure, when a voltage is applied to the outer electrodes 3A and 3B, the voltage is allowed to be applied in the thickness direction of the piezoelectric board 2 due to the inner electrodes 31.

In the regions L3 and L5, similarly, the inner electrodes 41 in the region L5 are conducted to the outer electrodes 4A and 4B formed on the two side surfaces of the piezoelectric board 2. In addition, as shown in FIG. 3B, the inner electrodes 51 in the region L3 are conducted to the outer electrodes 5A and 5B formed on the two side surfaces of the piezoelectric board 2. It should be noted that in the region L3, each of the plurality of inner electrodes 51 is configured to be conducted to both the outer electrodes 5A and 5B such that the outer electrodes 5A and 5B have the same potential. With this structure, when a voltage is applied between the outer electrodes 3A, 3B, 4A, and 4B in the regions L1 and L5 and the outer electrodes 5A and 5B in the region L3, the voltage is allowed to be applied in the length direction of the piezoelectric board 2 due to the inner electrodes 31.

It should be noted that the inner electrodes 51 in the region L3 are provided in order that the regions L2 and L4 are polarized in the longitudinal direction, and thus may be provided only at the boundary between the regions L2 and L3 and the boundary between the regions L3 and L4 as shown in FIG. 2B. In addition, the distances (the distances in the thickness direction) between the inner electrodes having a stacked structure shown in FIG. 3 are changeable as appropriate in accordance with a required capacitance. Moreover, the number of stacked inner electrode layers and piezoelectric layers is changeable as appropriate in accordance with a required capacitance.

In addition, each of the outer electrodes formed on the two side surfaces in the regions L1, L3, and L5 is formed, for example, by screen-printing an Ag paste on a member of the piezoelectric board 2 before firing and then firing the member.

FIG. 4 is a diagram showing wiring of the piezoelectric transformer 1 used in a step-up circuit and a simplified structure of the piezoelectric transformer 1. FIG. 4 is a schematic diagram of the piezoelectric transformer 1, and arrows shown in the regions L1, L2, L4, and L5 indicate polarization directions.

An input-side wire from an AC power source Vin is connected to the outer electrodes 3A and 3B and the outer electrodes 4A and 4B via an inductor L. A load R is connected to the outer electrodes 5A and 5B to which the inner electrodes 51 are conducted and which have the same potential. The inner electrodes 31 and 41 which are stacked alternately in the thickness direction of the piezoelectric board 2 are conducted to the outer electrodes 3A and 3B and the outer electrodes 4A and 4B. When an AC voltage is applied between the outer electrode 3A and the outer electrode 3B and between the outer electrode 4A and the outer electrode 4B from the AC power source Vin, the voltage is applied in the thickness direction of the piezoelectric board 2 via the inner electrodes 31 and 41, and a potential difference is created. In other words, an electric field is applied in the polarization direction in the regions L1 and L5. Then, longitudinal vibration is excited in a direction orthogonal to the polarization direction, namely, in the longitudinal direction of the piezoelectric board 2 due to se piezoelectric effect.

In the regions L2 and L4 in which the longitudinal vibration is excited, mechanical distortion occurs in the polarization direction, and a potential difference is created in the polarization direction (longitudinal direction) due to a piezoelectric effect. Due to the created potential difference, a portion at and near the region L3 becomes a high-voltage portion, and a high voltage is extracted from the outer electrodes 5A and 5B and applied to a first end of the load R. A second end of the load R is connected to the outer electrodes 3B and 4B and a reference potential of the circuit.

When the piezoelectric transformer 1 according to Embodiment 1 is driven in the higher-order mode (the (5λ/2) mode) as described above, the device size of the piezoelectric transformer 1 is not excessively reduced even in a high frequency of about 500 kHz, temperature increase of the device is suppressed, it is possible to reduce the heat loss, and high-efficient conversion of energy is enabled. In addition, in the piezoelectric transformer 1, displacement in the longitudinal direction of the piezoelectric board 2 is small in each of the center portions of the regions L1, L3, and L5. Therefore, when the piezoelectric transformer 1 is supported at the regions L1, L3, and L5 by the mounting substrate or a package, the vibration of the piezoelectric transformer 1 is not inhibited, and thus it is possible to prevent a decrease in the conversion efficiency. In addition, the wire is wired in the regions L1, L3, and L5 at which the displacement is small, whereby it is possible to prevent poor connection from occurring due to the vibration of the piezoelectric transformer 1 and it is possible to increase the reliability and durability of the mounted portion of the piezoelectric transformer 1.

In addition, each of the center portions of the regions L1, L2, L3, L4, and L5 becomes a stress-concentrated point in each region, and thus the stress-concentrated point is not located at a polarization interface (e.g., the boundary surface between the regions L1 and L2). Therefore, it is possible to prevent breakage or the like of the piezoelectric board 2 which is caused due to stress concentration.

Furthermore, it is possible to make the lengths of the regions L2 and L4 in the longitudinal direction long as compared to those in the related art. Thus, it is possible to increase the withstand voltage. As a result, a high voltage occurs at and near the region L3, and even when a high voltage is applied to the regions L2 and L4, the voltage does not exceed the withstand voltage of the piezoelectric board 2, and it is possible to increase the voltage conversion rate. It should be noted that the arrows indicating the polarization directions in the regions L1 and L5 in FIG. 4 indicate that the polarization directions are the thickness direction, and do not indicate the polarization directions in the regions L1 and L5 are orthogonal to the outer electrode surfaces.

It should be noted that in the present embodiment, the case where the piezoelectric transformer 1 is used as a step-up transformer has been described, but the piezoelectric transformer 1 may be used as a step-down transformer. FIG. 5 is a diagram showing wiring of the piezoelectric transformer 1 used in a step-down circuit and a simplified structure of the piezoelectric transformer 1.

An input-side wire from an AC current source Vin is connected to the outer electrodes 5A and 5B having the same potential. A load R is connected to the outer electrodes 3A and 3B and the outer electrodes 4A and 4B via an inductor L. When an AC voltage is applied between the outer electrodes 5A and 5B and the outer electrodes 3B and 4B from the AC current source, an electric field is applied in the polarization direction in the regions L2 and L4. Then, longitudinal vibration is excited in the polarization direction, namely, in the longitudinal direction of the piezoelectric board 2 due to an inverse piezoelectric longitudinal effect. In the regions L1 and L5 in which the longitudinal vibration is excited, mechanical distortion occurs in a direction orthogonal to the longitudinal direction (the polarization direction), and a potential difference is created in the polarization direction due to a piezoelectric transverse effect. Due to the potential difference, the regions L1 and L5 become low-voltage portions, and a low voltage is extracted from the outer electrodes 3A and 4A and applied to a first end of the load R. A second end of the load R is connected to the outer electrodes 3B and 4B and a reference potential of the circuit.

It should be noted that in the present embodiment, the width W of the piezoelectric transformer 1 is 2.0 mm (λ/3), but the width W may be equal to or smaller than λ/2 such that vibration in the width direction is not coupled to vibration in the length direction and the vibration of the entire piezoelectric transformer 1 is not unstable. FIG. 6 is a graph showing output power when the width W is varied. FIG. 6 shows a result of output measured when length L=15 mm, thickness T=1.0 mm, the width W is 1.0 mm, 1.25 mm, 1.5 mm, 1.75 mm, and 2.0 mm, the piezoelectric transformer 1 is configured as a step-down transformer and connected to a load resistance, a voltage is applied thereto, and an increase in the temperature of the piezoelectric transformer 1 is 30° C. As is obvious from the result, it is possible to confirm high output characteristics around a width of 1.5 mm (λ/4). As described above, it is possible to obtain high output when the width W is equal to or smaller than λ/2, and it is possible to obtain higher output when the width W is λ/4. The thickness T is preferably equal to or smaller than λ/4 as described above. Similarly, it is possible to obtain high output around a thickness T of 1.5 mm (λ/4) and at a width W of λ/4 or smaller.

In addition, a plurality of piezoelectric transformers 1 may be combined into a single piezoelectric transformer. FIGS. 7 and 8 each show an external perspective view of one piezoelectric transformer composed of a plurality of piezoelectric transformers 1 according Embodiment 1.

In FIG. 7, a plurality of the piezoelectric transformers 1 are arranged on a mounting substrate along the width direction and configured such that adjacent outer electrodes thereof are conducted to each other. Specifically, the outer electrodes 3B, 4B, and 5B of the piezoelectric transformer 1 and the outer electrodes 3A, 4A, and 5A of the piezoelectric transformer 1 adjacent thereto in the width direction are conducted to each other.

In FIG. 8, the piezoelectric transformers 1 are stacked in the thickness direction and the outer electrodes adjacent to each other in the stacking direction are conducted to each other, whereby the piezoelectric transformers 1 are made into one unit. Specifically, the outer electrodes 3A, the outer electrodes 4A, and the outer electrodes 5A of the respective piezoelectric transformers 1 stacked in the thickness direction are conducted to each other by plate-shaped conductors 5. In addition, although not shown in FIG. 8, the outer electrodes 3B, the outer electrodes 4B, and the outer electrodes 5B are conducted to each other by plate-shaped conductors.

In general, when a driving frequency is high, the size of a piezoelectric transformer is reduced. Thus, in order to obtain high-efficient output, the allowable loss in the piezoelectric transformer is decreased. Thus, when a plurality of the piezoelectric transformers 1 according to the present embodiment from which high output is obtained are arranged as shown in FIG. 7 or 8, it is possible to increase the transmission power, and further it is possible to enhance the heat dissipation. When the piezoelectric transformer 1 longitudinally vibrates in a higher-order mode in the length direction, not only displacement in the length direction but also displacement in the width direction occur. Gaps are preferably provided between a plurality of the arranged piezoelectric transformers 1 such that vibrations thereof in the width direction are not inhibited.

In addition, when a piezoelectric transformer having the same size as that shown in FIG. 7 or 8 is configured from one piezoelectric board, the length in the width direction is longer than λ/2, and unnecessary vibration and its higher-order mode occur in the width direction. There is a concern that this is coupled to vibration in the longitudinal direction. Thus, when a plurality of the piezoelectric transformers 1 according to the present embodiment are arranged to configure one piezoelectric transformer, in is possible to avoid unnecessary resonance.

### Embodiment 2

Next, a piezoelectric transformer according to Embodiment 2 will be described. In the present embodiment, the piezoelectric transformer is configured such that a plurality of electrodes are stacked in the longitudinal direction of the piezoelectric board 2 in the regions L1 and L5. In addition, in the present embodiment, the polarization directions of the piezoelectric board 2 in the regions L1 and L5 is the longitudinal direction. The difference from Embodiment 1 will be described below.

FIG. 9 is a side cross-sectional view of the piezoelectric transformer according to Embodiment 2 and corresponds to FIG. 2. The piezoelectric transformer 1A according to the present embodiment is configured such that the inner electrodes 31 and the inner electrodes 41 are alternately stacked in the longitudinal direction of the piezoelectric board 2. In addition, the piezoelectric board 2 is subjected to poling treatment such that the polarization directions in the regions L1 and L5 are the longitudinal direction. Moreover, in the region L3, inner electrodes 51 are provided at the boundaries between the regions L2 and L3 and at the boundaries between the regions L3 and L4, are conducted to the outer electrodes 5A and 5B, and have the same potential as that of the outer electrodes 5A and 5B.

In the piezoelectric transformer 1A, similarly to Embodiment 1, when an AC voltage is applied to the outer electrodes 3A and 3B and the outer electrodes 4A and 4B, the regions L1 and L5 displace in the longitudinal direction, which is the polarization direction, due to an inverse piezoelectric effect. When the regions L1 and L5 displace in the longitudinal direction, the displacement is transmitted to the regions L2 and L4 and the regions L2 and L4 displace in the longitudinal direction. As a result, a potential difference is created in the polarization direction, namely, in the longitudinal direction due to a piezoelectric effect. Due to the potential difference created between the region L3 and the regions L1 and L5, the regions L2 and L4 become high-voltage portions, and a voltage is extracted from the outer electrodes 5A and 5B.

Even with the configuration of the piezoelectric transformer 1A according to the present embodiment, it is possible to obtain the same advantageous effects as those in Embodiment 1.

### Embodiment 3

In Embodiment 3, the case will be described in which the piezoelectric transformer according to Embodiments 1 and 2 is used in a wireless power transmission system. The wireless power transmission system includes a power transmitting apparatus and a power receiving apparatus. The power receiving apparatus is, for example, a portable electronic apparatus including a secondary battery. Examples of the portable electronic apparatus include a cellular phone, a personal digital assistant (PDA), a portable music player, a notebook type personal computer (PC), and a digital camera. The power transmitting apparatus is a charging cradle on which the power receiving apparatus is placed and which is used to charge the secondary battery of the power receiving apparatus. Each of the power transmitting apparatus and the power receiving apparatus includes an active electrode and a passive electrode. By capacitive coupling between the active electrodes and between the passive electrodes, power is transmitted from the power transmitting apparatus to the power receiving apparatus.

FIG. 10 is a diagram showing a circuit configuration of the wireless power transmission system. In the present embodiment, a piezoelectric transformer is used in a step-down circuit included in a power receiving apparatus 200.

A high frequency high voltage generation circuit 101 of a power transmitting apparatus 100 generates a high frequency voltage of, for example, 100 kHz to several tens MHz. The voltage generated by the high frequency high voltage generation circuit 101 is applied between an active electrode 103 and a passive electrode 104 via an inductor La. A capacitor CG is a capacitance mainly by the active electrode 103 and the passive electrode 104 and constitutes a resonant circuit together with the inductor La.

A step-down circuit composed of the piezoelectric transformer 1 and an inductor Lb is connected between an active electrode 203 and a passive electrode 204 of the power receiving apparatus 200. A capacitance element CL is a capacitance mainly by the active electrode 203 and the passive electrode 204.

Coupling between a coupling electrode by the active electrode 103 and the passive electrode 104 of the power transmitting apparatus 100 and a coupling electrode by the active electrode 203 and the passive electrode 204 of the power receiving apparatus 200 can be represented as coupling via a mutual capacitance Cm.

As described in Embodiments 1 and 2, the piezoelectric transformer 1 steps down a voltage applied between the outer electrodes 5A and 5B and the outer electrodes 3B and 4B (or the outer electrodes 3A and 4A) and outputs the voltage to the outer electrodes 3A and 4A (or the outer electrodes 3B and 4B). The output voltage is supplied to a load circuit RL. The load circuit RL includes, for example, a rectifying circuit and charges the secondary battery of the power receiving apparatus 200.

When the low-loss piezoelectric transformer 1 is used in the step-down circuit as described above, it is possible to realize a low-loss small-size step-down circuit. As a result, it is possible to reduce the size of the power receiving apparatus 200.

FIG. 11 is a diagram showing a circuit configuration of a wireless power transmission system when two piezoelectric transformers 1 are used.

In FIG. 11, a power receiving apparatus 200 includes a piezoelectric transformer module 10 including a piezoelectric transformer 11 which outputs a positive voltage of an AC voltage and a piezoelectric transformer 12 which outputs a negative voltage thereof, and balance-unbalance conversion is provided. The outer electrodes 5A and 5B of the two piezoelectric transformers 11 and 12 are connected to a voltage input terminal T4 connected to the active electrode 203. In addition, the outer electrodes 3A and 4A of the piezoelectric transformer 11 are connected to a first output terminal T1 via a rectifying diode D1, and the outer electrodes 3B and 4B thereof are connected to a third output terminal T3 connected to the passive electrode 204. The outer electrodes 3A and 4A of the piezoelectric transformer 12 are connected to the third output terminal T3, and the outer electrodes 3B and 4B thereof are connected to a second output terminal T2 via a diode D2.

In addition, one end of a matching or resonance inductor Lb1 is connected to the first output terminal T1 via the diode (first rectifying element) D1, and the other end thereof is connected to the third output terminal T3. One end of a matching or resonance inductor Lb2 is connected to the second output terminal T2 via the diode (second rectifying element) D2, and the other end thereof is connected to the third output terminal T3. Moreover, the first output terminal T1 and the second output terminal T2 are connected to a load R via a smoothing circuit composed of an inductor Lc and a capacitor C1.

In the circuit configuration, by providing balanced output, matching with a balanced-input type rectifying circuit is good, and stable operation is enabled.

It should be noted that the polarization direction in the piezoelectric transformer is not limited to those in the above-described embodiments. FIGS. 12A, 12B, 12C, 13A, 13B, 14A, and 14B are diagrams illustrating variations of the polarization direction in the piezoelectric transformer. In modifications described below, a description will be given with a configuration in which the outer electrodes which are provided on the opposed side surfaces of the piezoelectric board in the above-described embodiments are provided so as to be opposed to each other in the thickness direction of the piezoelectric board.

FIGS. 12A, 12B, and 12C show the case where the regions L1 and L5 exert a transverse effect in which a vibration direction and a polarization direction are orthogonal to each other and the regions L2 and L4 exert a longitudinal effect in which a vibration direction and a polarization direction are the same. As shown in FIG. 12A, the polarization directions in the regions L2 and L4 may be opposite to those in Embodiment 1. In addition, as shown in FIG. 12B, the polarization direction in the region L5 may be opposite to the polarization direction in the region L1. Furthermore, as shown in FIG. 12C, the polarization directions in the regions L2 and L4 may be opposite to those in Embodiment 1, and the polarization direction in the region L5 may be opposite to the polarization direction in the region L1.

FIGS. 13A, 13B, 14A, and 14B show the case where the regions L1, L2, L4, and L5 exert a longitudinal effect in which a vibration direction and a polarization direction are the same. In addition, in each of FIGS. 13A, 13B, 14A, and 14B, a configuration in which the shapes of the outer electrodes in the regions L1 and L5 are bilaterally symmetrical about the region L3 to have polarity in the same direction in the longitudinal direction is shown in the upper diagram, and a configuration in which the shapes of the outer electrodes in the regions L1 and L5 are bilaterally symmetrical about the region L3 to have the same polarity in the same direction is shown in the lower diagram.

As shown in FIG. 13A, the polarization directions in the regions L1 and L2 may be a direction to the region L5 side, and the polarization directions in the regions L4 and L5 may be a direction to the region L1 side. In addition, as shown in FIG. 13B, the polarization directions in the regions L1 and L2 may be opposed to each other, and the polarization directions in the regions L4 and L5 may be opposed to each other.

Furthermore, as shown in FIG. 14A, the polarization directions in the regions L1, L2, and L5 may coincide with each other, and the polarization direction in the region L4 may be opposite thereto. Moreover, as shown in FIG. 14B, the polarization directions in the regions L1, L4, and L5 may coincide with each other, and the polarization direction in the region L2 may be opposite thereto.

In addition, in the above-described embodiments, in the case of a step-up operation, the region L3 at the center in the longitudinal direction is an output portion, but electrodes may be provided in the regions L2 and L4 such that the regions L2 and L4 are output portions. FIGS. 15A, 15B, 15C, 15D, 16A, 16B, 16C, and 16D show a piezoelectric transformer when the regions of the input and output portions are changed. The centers of the regions L1, L2, L4, and L5 in the longitudinal direction are positions (nodes) at which the displacement of the piezoelectric board becomes minimum, and each of the piezoelectric transformers in FIGS. 15A, 15B, 15C, 15D, 16A, 16B, 16C, and 16D is supported at the regions L1, L2, L4, and L5 by a mounting substrate or a package.

FIGS. 15A, 15B, 15C, and 15D show the case where the regions L1, L2, L4, and L5 exert a transverse effect in which a vibration direction and a polarization direction are orthogonal to each other. In FIGS. 15A, 15B, 15C, and 15D, a shared outer electrode 7A is provided at the lower side of the piezoelectric board 2 in the regions L4 and L5, and outer electrodes 7B and 7C opposed to the outer electrode 7A are provided in the regions L4 and L5, respectively. The polarization directions in the regions L4 and L5 are an upward direction.

In FIG. 15A, a shared outer electrode 6A is provided at the upper side of the piezoelectric board 2 in the regions L1 and L2, and outer electrodes 6B and 6C opposed to the outer electrode 6A are provided in the regions L1 and L2, respectively. The polarization directions in the regions L1 and L2 are a downward direction. In this case, it is possible to extract a stepped-up voltage from the outer electrodes 6C and 7B. The region L3 is non-polarized, opposed electrodes are not provided in the region L3 in FIGS. 15A, 15B, 15D, 16A, 16B, 16C, and 16D. In FIG. 15A, the shared outer electrode 6A is provided at the upper side of the piezoelectric board 2 in the regions L1 and L2, but the outer electrode 6A may be individually provided in the regions L1 and L2. In addition, the shared outer electrode 7A may be individually provided in the regions L4 and L5.

In FIG. 15B, similarly to FIG. 15A, the outer electrodes 6A, 6B, and 6C are provided. The polarization direction in the region L1 is an upward direction, and the polarization direction in the region L2 is a downward direction. In this case, it is possible to extract a stepped-up voltage from the outer electrodes 6C and 7B.

In FIG. 15C, the shared outer electrode 6A is provided at the lower side of the piezoelectric board 2 in the regions L1 and L2, and the outer electrodes 6B and 6C opposed to the outer electrode 6A are provided in the regions L1 and L2, respectively. The polarization directions in the regions L1 and L2 are an upward direction. In this case, it is possible to extract a stepped-up voltage from the outer electrodes 6C and 7B.

In FIG. 15D, similarly to FIG. 15C, the outer electrodes 6A, 6B, and 60 are provided. The polarization direction in the region L1 is a downward direction, and the polarization direction in the region L2 is an upward direction. In this case, it is possible to extract a stepped-up voltage from the outer electrodes 6C and 7B.

FIGS. 16A, 16B, 16C, and 16D show the case where the regions L1 and L5 exert a longitudinal effect in which a vibration direction and a polarization direction are the same and the regions L2 and L4 exert a transverse effect in which a vibration direction and a polarization direction are orthogonal to each other. In addition, the shared outer electrode 7A is provided at the lower side of the piezoelectric board 2 in the regions L4 and L5, and the outer electrodes 7B and 7C opposed to the outer electrode 7A are provided in the regions L4 and L5, respectively. The outer electrodes 7A and 7C have inner electrodes such that a voltage is applied in the longitudinal direction. The polarization direction in the region L4 is an upward direction, and the polarization direction in the region L5 is a direction to the region L1 side.

In FIG. 16A, the shared outer electrode 6A is provided at the upper side of the piezoelectric board 2 in the regions L1 and L2, and the outer electrodes 6B and 6C opposed to the outer electrode 6A provided in the regions L1 and L2, respectively. The outer electrodes 6A and 6B have inner electrodes such that a voltage is applied in the longitudinal direction, and are configured to have polarity in the same direction as the region L5 in the longitudinal direction in FIG. 16A. The polarization direction in the region L1 is a direction to the outer side portion of the piezoelectric board 2, and the polarization direction in the region L2 is an upward direction. In this case, it is possible to extract a stepped-up voltage from the outer electrodes 6C and 7B.

In FIG. 16B, the outer electrodes have the same configuration as in FIG. 16A, the polarization direction in the region L1 is a direction to the region L5 side, and the polarization direction in the region L2 is a downward direction. In this case, it is possible to extract a stepped-up voltage from the outer electrodes 6C and 7B.

In FIG. 16C, the shared outer electrode 6A is provided at the lower side of the piezoelectric board 2 in the regions L1 and L2, and the outer electrodes 6B and 6C opposed to the outer electrode 6A are provided in the regions L1 and L2, respectively. The outer electrodes 6A and 6B have inner electrodes such that a voltage is applied in the longitudinal direction, and are configured to have polarity in a direction opposite to that in the region L5 in the longitudinal direction in FIG. 16C. In this case, it is possible to extract a stepped-up voltage from the outer electrodes 6C and 7B.

In FIG. 16D, the outer electrodes have the same configuration as in FIG. 16C, the polarization direction in the region L1 is a direction to the outer side portion of the piezoelectric board 2, and the polarization direction in the region L2 is an upward direction. In this case, it is possible to extract a stepped-up voltage from the outer electrodes 6C and 7B. It should be noted that in the configurations in FIGS. 15A, 15B, 15C, 15D, 16A, 16B, 16C, and 16D, the distances between the inner electrodes and the number of stacked inner electrode layers and piezoelectric layers is adjusted such that the capacitances in the regions L2 and L4 are larger than the capacitances in the regions L1 and L5, whereby it is possible to extract a stepped-down voltage from the outer electrodes 6C and 7B in the regions L2 and L4.

In the above-described embodiments, the piezoelectric transformer 1 vibrates in the (5λ/2) resonant mode, but may vibrate in a further higher-order mode.

FIGS. 17A and 17B are cross-sectional views of a piezoelectric transformer which vibrates in a (7λ/2) resonant mode. When the length of the piezoelectric transformer shown in FIGS. 17A and 17B is L, the piezoelectric board 2 is divided into seven equal regions in the longitudinal direction, and these regions each having a length of L/7 (i.e., λ/2) in the longitudinal direction are designated by L1 to L7. The centers of the regions L2, L4, and L6 in the longitudinal direction are positions (nodes) at which the displacement of the piezoelectric board 2 becomes minimum, and the piezoelectric transformer in FIG. 17A is supported at the regions L2, L4, and L6 by a mounting substrate. In addition, opposed outer electrodes 8A and 8B are provided in the region L1. Opposed outer electrodes 9A and 9B are provided in the region L2. Opposed outer electrodes 10A and 10B are provided in the region L4. Opposed outer electrodes 11A and 11B are provided in the region L6. Opposed outer electrodes 12A and 12B are provided in the region L7.

In FIG. 17A, the polarization directions in the regions L1, L2, L6, and L7 are an upward direction, and the polarization directions in the regions L3 and L5 are directions opposed to each other. The region L4 is non-polarized. In this case, although not shown, the outer electrodes 8A and 9B are connected to each other, and the outer electrodes 8B and 9A are connected to each other. In addition, the outer electrodes 11A and 12B are connected to each other, and the outer electrodes 11B and 12A are connected to each other. When an AC voltage is applied between the outer electrodes 8A and 9B and the outer electrodes 8B and 9A and between the outer electrodes 11A and 12B and the outer electrodes 11B and 12A, the regions L1, L2, L6, and L7 exert a transverse effect, the regions L3 and L5 exert a longitudinal effect, and thus it is possible to extract a stepped-up voltage from the outer electrodes 10A and 10B in the region L4.

In FIG. 17B, the polarization directions in the regions L1 and L7 are a downward direction, the polarization directions in the regions L2 and L6 are an upward direction, and the polarization directions in the regions L3 and L5 are directions opposed to each other. In this case, the outer electrodes 8A and 9A are connected to each other, and the outer electrodes 8B and 9B are connected to each other. In addition, the outer electrodes 11A and 12A are connected to each other, and the outer electrodes 11B and 12B are connected to each other. When an AC voltage is applied between the outer electrodes 8A and 9A and the outer electrodes 8B and 9B and between the outer electrodes 11A and 12A and the outer electrodes 11B and 12B, the regions L1, L2, L6, and L7 exert a transverse effect, the regions L3 and L5 exert a longitudinal effect, and thus it is possible to extract a stepped-up voltage from the outer electrodes 10A and 10B in the region L4.

FIGS. 18A and 18B are cross-sectional views of a piezoelectric transformer which vibrates in a (9λ/2) resonant mode. When the length of the piezoelectric transformer shown in FIGS. 18A and 18B is L, the piezoelectric board 2 is divided into nine regions in the longitudinal direction, and these regions each having a length of L/9 (i.e., λ/2) in the longitudinal direction are designated by L1 to L9. The centers of the regions L3, L5, and L7 in the longitudinal direction are positions (nodes) at which the displacement of the piezoelectric board 2 becomes minimum, and the piezoelectric transformer in FIGS. 18A and 18B is supported at the regions L3, L5, and L7 by a mounting substrate. In addition, opposed outer electrodes 8A and 8B are provided in the region L1. Opposed outer electrodes 9A and 9B are provided in the region L2. Opposed outer electrodes 10A and 10B are provided in the region L3. Opposed outer electrodes 11A and 11B are provided in the region L5. Opposed outer electrodes 12A and 12B are provided in the region L7. Opposed outer electrodes 13A and 13B are provided in the region L8. Opposed outer electrodes 14A and 14B are provided in the region L9.

In FIG. 18A, the polarization directions in the regions L1, L2, L3, L7, L8, and L9 are an upward direction, and the polarization directions in the regions L4 and L6 are directions opposed to each other. The region L5 is non-polarized. In this case, although not shown, the outer electrodes 8A, 9B, and 10A are connected to each other, and the outer electrodes 8B, 9A, and 10B are connected to each other. In addition, the outer electrodes 12A, 13B, and 14A are connected to each other, and the outer electrodes 12B, 13A, and 14B are connected to each other. When an AC voltage is applied between the outer electrodes 8A, 9B, and 10A and the outer electrodes 8B, 9A, and 10B and between the outer electrodes 12A, 13B, and 14A and the outer electrodes 12B, 13A, and 14B, the regions L1, L2, L3, L7, L8, and L9 exert a transverse effect, the regions L4 and L6 exert a longitudinal effect, and thus it is possible to extract a stepped-up voltage from the outer electrodes 11A and 11B in the region L5.

In FIG. 18B, the polarization directions in the regions L2 and L8 are a downward direction, and the polarization directions in the other regions are the same as in FIG. 18A. In this case, the outer electrodes 8A, 9A, and 10A are connected to each other, and the outer electrodes 8B, 9B, and 10B are connected to each other. In addition, the outer electrodes 12A, 13A, and 14A are connected to each other, and the outer electrodes 12B, 13B, and 14B are connected to each other. When an AC voltage is applied between the outer electrodes 8A, 9A, and 10A and the outer electrodes 8B, 9B, and 10B and between the outer electrodes 12A, 13A, and 14A and the outer electrodes 12B, 13B, and 14B, the regions L1, L2, L3, L7, L8, and L9 exert a transverse effect, the regions L4 and L6 exert a longitudinal effect, and thus it is possible to extract a stepped-up voltage from the outer electrodes 11A and 11B in the region L5.

FIG. 19 is a cross-sectional view of a piezoelectric transformer which vibrates in a (11λ/2) resonant mode. When the length of the piezoelectric transformer shown in FIG. 19 is L, the piezoelectric board 2 is divided into eleven regions in the longitudinal direction, and these regions each having a length of L/11 (i.e., λ/2) in the longitudinal direction are designated by L1 to L11. The centers of regions L4, L6, and L8 in the longitudinal direction are positions (nodes) at which the displacement of the piezoelectric board 2 becomes minimum, and the piezoelectric transformer in FIG. 19 is supported at the regions L4, L6, and L8 by a mounting substrate. In order to reduce stress on the mounted portions, the mounted portions are preferably located at and near the center. In addition, outer electrodes 8A, 9A, 10A, 11A, 12A, 13A, 14A, 15A, and 16A are provided at the upper side of the regions L1, L2, L3, L4, L6, L8, L9, L10, and L11, and outer electrodes 8B, 9B, 10B, 11B, 12B, 13B, 14B, 15B, and 16B which are opposed to these electrodes are provided.

In FIG. 19, the polarization directions in the regions L1, L3, L9, and L11 are a downward direction, the polarization directions in the regions L2, L4, L8, and L10 are an upward direction, and the polarization directions in the regions L5 and L7 are directions opposed to each other. The region L6 is non-polarized. In this case, the outer electrodes 8A, 9A, 10A, and 11A are connected to each other, and the outer electrodes 8B, 9B, 10B, and 11B are connected to each other. In addition, the outer electrodes 13A, 14A, 15A, and 16A are connected to each other, and the outer electrodes 13B, 14B, 15B, and 16B are connected to each other. When an AC voltage is applied between the outer electrodes 8A, 9A, 10A, and 11A and the outer electrodes 8B, 9B, 10B, and 11B and between the outer electrodes 13A, 14A, 15A, and 16A and the outer electrodes 13B, 14B, 15B, and 16B, the regions L1, L2, L4, L8, L9, L10, and L11 exert a transverse effect, the regions L5 and L7 exert a longitudinal effect, and thus it is possible to extract a stepped-up voltage from the outer electrodes 12A and 12B in the region L6.

FIGS. 17B, 18B, and 19 are cross-sectional views showing wiring connecting the electrodes of the piezoelectric transformers which vibrate in the (7λ/2) resonant mode, the (9λ/2) resonant mode, and the (11λ/2) resonant mode. When a resonant mode that is the (7λ/2) resonant mode or higher is used, as compared to the case where the (5λ/2) resonant mode is used, it is made possible to adjust the impedance in the end portion region of the piezoelectric board, and it is made possible to adjust the step-up ratio or the step-down ratio. In addition, it is possible to reduce the number of stacked layers and it is possible to simplify the structure.

Here, the case of using a (2n+1)-order resonant mode will be considered (n is an integer that is not smaller than 3). FIG. 20 is a cross-sectional view of a piezoelectric transformer which vibrates in a {(2n+1)λ/2} resonant mode. When the length of the piezoelectric transformer shown in FIG. 20 is L, the piezoelectric board 2 is divided into (2n+1) equal regions, and these regions each having a length of L/(2n+1) (i.e., λ/2) in the longitudinal direction are designated by L1 to L(2n+1).

In this case, the middle region L(n+1) is a non-polarized region. When k (k is a positive integer that is smaller than n) regions at each side thereof are regions polarized in the length direction, and further (n−k) regions at each side thereof are regions polarized in the thickness direction, L1 to L(n−k) and L(n+k+2) to L(2n+1) are regions polarized in the thickness direction. In addition, L(n−k+1) to L(n) and L(n+2) to L(n+k+1) are regions polarized in the length direction. Furthermore, L(n+1) is a non-polarized region.

When an indication amount for qualitatively taking the step-up ratio (or the step-down ratio) is S, it is possible to define the indication amount as S=k(n−k), and S=−(k−n/2)²+n²/4 as shown in FIG. 21. When k=n/2, S becomes maximum. In consideration of the condition that both k and n are positive integers, S becomes maximum when n=2m (m is a positive integer) and k=m. In other words, it is made possible to increase the step-up ratio (or the step-down ratio).

The specific configuration and the like of the piezoelectric transformer may be changed as appropriate, the advantageous effects described in the aforementioned embodiments are merely described as the most preferred advantageous effects provided from the present invention, and the advantageous effects provided by the present invention are not limited to those described in the aforementioned embodiments. The embodiments using multilayer structure have been described, but a single plate structure may be used.

### REFERENCE SIGNS LIST

1 piezoelectric transformer
2 piezoelectric board (piezoelectric body)
3A, 3B outer electrode (first electrode, second electrode)
4A, 4B outer electrode (first electrode, second electrode)
5A, 5B outer electrode (third electrode)
L1 region (first region)
L2 region (second region)
L3 region (third region)
L4 region (fourth end portion)
L5 region (fifth end portion)

1. A piezoelectric transformer using a fifth-order longitudinal vibration mode, the piezoelectric transformer comprising:
a piezoelectric board having:
a length of 5λ/2, a width less than λ/2, and a thickness less than λ/2, wherein λ is the wave length of the vibration mode, and
five regions dividing the piezoelectric board along the length of the piezoelectric board,
wherein the first region and the fifth region are disposed adjacent to respective outer edges of the piezoelectric board and are polarized in a direction of either the thickness or the length of the piezoelectric board,
wherein the second region and the fourth region are polarized in the direction of the length of the piezoelectric board,
wherein the third region is disposed between the first region and the fifth region and is non-polarized, and
wherein the second region is disposed between the first region and the third region and the fourth region is disposed between the third region and the fifth region; and
a first pair of opposing electrodes and a second pair of opposing electrodes disposed in the first and fifth regions, respectively, and arranged in the direction of polarization of the respective regions.

2. The piezoelectric transformer according to claim 1, further comprising at least one third electrode disposed in the third region.

3. The piezoelectric transformer according to claim 1, wherein one of the width and the thickness of the piezoelectric board is λ/4, and the other of the width and the thickness is equal to or less than λ/4.

4. The piezoelectric transformer according to claim 1, wherein the first pair of electrodes and the second pair of electrodes oppose each other in the thickness direction and the first region and the fifth region are polarized in the thickness direction.

5. The piezoelectric transformer according to claim 1, wherein the first pair of electrodes and the second pair of electrodes oppose each other in the length direction and the first region and the fifth region are polarized in the length direction.

6. The piezoelectric transformer according to claim 1, wherein the piezoelectric board is supported by a mounting substrate at the third region, the first region, and the fifth region.

7. The piezoelectric transformer according to claim 1, wherein the second region and the fourth region are polarized in a direction of the thickness of the piezoelectric board.

8. The piezoelectric transformer according to claim 7, further comprising a third pair of opposing electrodes and a fourth pair of opposing electrodes disposed in each of the second region and the fourth region, respectively, and arranged in the direction of polarization of the respective regions.

9. The piezoelectric transformer according to claim 8, wherein the piezoelectric board is supported by a mounting substrate at the first region, the second region, the fourth region, and the fifth region.

10. A piezoelectric transformer module comprising:
at least two piezoelectric transformers according claim 2;
a voltage input terminal;
a ground terminal; and
a first output terminal and a second output terminal, wherein in the first piezoelectric transformer and the second piezoelectric transformer, the third electrode is connected to the voltage input terminal,
wherein in the first piezoelectric transformer, a first electrode of each of the first and second pairs of opposing electrodes is connected to the first output terminal, and a second electrode of each of the first and second pairs of opposing electrodes is connected to the ground terminal, and
wherein in the second piezoelectric transformer, a first electrode of each of the first and second pairs of opposing electrodes is connected to the ground terminal, and a second electrode of each of the first and second pairs of opposing electrodes is connected to the second output terminal.

11. The piezoelectric transformer module according to claim 10, further comprising:
a first rectifying element connected between each of the first electrodes and the first output terminal; and
a second rectifying element connected between each of the second electrodes and the second output terminal.

12. A piezoelectric transformer module comprising:
a plurality of piezoelectric transformers according claim 2,
wherein the plurality of piezoelectric transformers are stacked along a thickness direction,
wherein a first electrode of each of the first and second pairs of opposing electrodes of a first piezoelectric transformer of the piezoelectric transformers and a second electrode of each of the first and second pairs of opposing electrodes of a second piezoelectric transformer adjacent to the first piezoelectric transformer in the thickness direction are conducted to each other, and
wherein the third electrodes of the first and second piezoelectric transformers are conducted to each other.

13. A piezoelectric transformer module comprising:
a plurality of piezoelectric transformers according to claim 2,
wherein the plurality of piezoelectric transformers are stacked in a width direction, and
wherein first electrodes of each of the first and second pairs of opposing electrodes of adjacent piezoelectric transformers are conducted to each other, second electrodes of each of the first and second pairs of opposing electrodes of the adjacent piezoelectric transformers are conducted to each other, and the third electrodes of the adjacent piezoelectric transformers are conducted to each other.

14. The piezoelectric transformer according to claim 1, wherein the first region and the fifth region each comprise a plurality of inner electrodes.

15. The piezoelectric transformer according to claim 14,
wherein the plurality of inner electrodes in the first region are alternately conducted to the first pair of opposing electrodes, and
wherein the plurality of inner electrodes in the fifth region are alternately conducted to the second pair of opposing electrodes.

16. The piezoelectric transformer according to claim 15, further comprising a pair of third electrodes disposed in the third region and opposing each other.

17. The piezoelectric transformer according to claim 16, wherein the third region comprises a plurality of inner electrodes that are alternately conducted to the pair of third electrodes.

18. A piezoelectric transformer using a (2n+1)-order longitudinal vibration mode where n is an integer greater than 2, the piezoelectric transformer comprising:
a piezoelectric board having:
a length of (2n+1)×λ/2, a width less than λ/2, and a thickness less than λ/2, wherein λ is the wave length of the vibration mode, and (2n+1)th regions dividing the piezoelectric board along a length direction,
wherein the first region to the (n−k)th region and the (n+k+2)th region to the (2n+1)th region are each polarized in a direction of the thickness of the piezoelectric board, where k is a positive integer smaller than n,
wherein the (n−k+1)th region to nth region and the (n+2)th region to the (n+k+1)th region are polarized in a direction of the length of the piezoelectric board,
wherein the (n+1)th region is non-polarized;
first pairs of opposing electrodes and second pairs of opposing electrodes disposed in the first region to the (n−k)th region and the (n+k+2)th region to the (2n+1)th region, respectively, and arranged in the direction of polarization of the respective regions; and
at least one third electrode disposed between the (n−k+1)th region to the nth region and the (n+2)th region to the (n+k+1)th region.

19. The piezoelectric transformer according to claim 18, wherein n=2m, where m is a positive integer, and k=m.

20. A wireless power transmission system comprising:
a power transmitting apparatus including a transmission-side active electrode, a transmission-side passive electrode, and a voltage generation circuit configured to apply a voltage between the transmission-side active electrode and the transmission-side passive electrode; and
a power receiving apparatus including a reception-side active electrode adjacent to the transmission-side active electrode and a reception-side passive electrode adjacent to the transmission-side passive electrode when the power receiving apparatus is positioned on the power transmitting apparatus, a step-down circuit configured to step down a voltage generated between the reception-side active electrode and the reception-side passive electrode, and a load circuit configured to receive an output voltage of the step-down circuit,
wherein the transmission-side active electrode and the reception-side active electrode are capacitively coupled to each other to transmit power from the power transmitting apparatus to the power receiving apparatus, and
wherein the wireless power transmission system comprises a piezoelectric transformer using a fifth-order longitudinal vibration mode, the piezoelectric transforming including:
a piezoelectric board having:
a length of 5λ/2, a width less than λ/2, and a thickness less than λ/2, wherein λ is the wave length of the vibration mode, and
five regions dividing the piezoelectric board along the length of the piezoelectric board,
wherein the first region and the fifth region are disposed adjacent to respective outer edges of the piezoelectric board and are polarized in a direction of either the thickness or the length of the piezoelectric board,
wherein the third region is disposed between the first region and the fifth region and is non-polarized, and
wherein the second region is disposed between the first region and the third region and the fourth region is disposed between the third region and the fifth region;
a first pair of opposing electrodes and a second pair of opposing electrodes disposed in the first and fifth regions, respectively, and arranged in the direction of polarization of the respective regions; and
a third electrode disposed in the third region.
